(19) United States
(12) Patent Application Publication
(10) Pub. No.: US 2026/0016530 A1
(43) Pub. Date: Jan. 15, 2026

(54) TESTING CIRCUIT, TESTING APPARATUS, AND TESTING METHOD

(71) Applicant: ADVANTEST CORPORATION, Tokyo (JP)

(72) Inventors: Yusuke ASADA, Saitama (JP); Tomohiro UENO, Saitama (JP); Kensuke SOEDA, Saitama (JP)

(21) Appl. No.: 19/251,805

(22) Filed: Jun. 27, 2025

(30) Foreign Application Priority Data
Jul. 11, 2024 (JP) 2024-111486

(51) Int. Cl. G01R 31/28

(52) U.S. Cl. CPC G01R 31/2841; G01R 31/2837

(57) ABSTRACT

Provided is a testing circuit including a measurement circuit which generates an output voltage and performs a voltage application current measurement test of a device under test by using the output voltage, a pulse generation circuit which generates a pulse signal by using the output voltage of the measurement circuit in a functional test of a device under test to supply the pulse signal to a terminal of a device under test and causes the output voltage of the measurement circuit to pass therethrough in the voltage application current measurement test to supply the output voltage to a terminal of a device under test as a test voltage, and an output end feedback line which is connected to an output end side of the pulse generation circuit and feeds back a voltage on the output end side to the measurement circuit.

The contents of the following patent application(s) are incorporated herein by reference: NO. 2024-111486 filed in JP on Jul. 11, 2024.

### BACKGROUND

### 1. Technical Field

The present invention relates to a testing circuit, a testing apparatus, and a testing method.

### 2. Related Art

Patent document 1 describes a “testing apparatus including a determination unit which determines pass or fail of a device under test based on a load voltage or a load current applied to the device under test when a test signal of a constant current or a constant voltage is supplied from a driver circuit to the device under test, in which the driver circuit includes a driver unit which outputs the test signal, a power source current detection unit which detects a power source current supplied to the driver unit, and an output control unit which controls a voltage or a current of the test signal output by the driver unit to a predetermined value based on the power source current detected by the power source current detection unit (paragraph 0008 in Patent document 1).

Patent document 2 describes that a DCL 302 supplies a control output to an output stage 310 via a DAC 304, that a feedback from an output stage 310 is supplied to each of a current ADC 306 and a voltage ADC output terminal 320 via a current sense element 312 and a voltage sense element 314, that a current feedback is obtained from a current which flows through a current shunt resistance 316, that a voltage feedback is obtained between output terminals 320 and 322, and the like (paragraph 0034 of Patent document 2).

Patent document 3 describes a “power source apparatus including an analog-to-digital converter for voltage which receives an analog voltage observation value according to a power source voltage supplied to the power source terminal of the device via a feedback line and generates a digital voltage observation value by performing an analog-to-digital conversion of the analog voltage observation value, a digital arithmetic unit which generates a main control value which is adjusted such that the digital voltage observation value matches the voltage target value by digital arithmetic processing, a main digital-to-analog converter which performs a digital-to-analog conversion of the main control value and supplies an analog power source signal obtained as a result to a power source terminal of the device via the power source line, a main detection resistance which is provided on a path of the power source line and in which its resistance value can be switched, a main sense amplifier which generates an analog main current observation value indicating a current amount of a power source current which flows through the power source line based on a voltage between both ends of the main detection resistance, and an analog-to-digital converter for main current which performs an analog-to-digital conversion of the analog main current observation value to generate a digital main current observation value” (claim 1 of Patent document 3).

### RELATED ART DOCUMENTS

### Patent Documents

Patent Document 1: PCT International Publication No. WO 2009/157126
Patent Document 2: Specification of U.S. Patent Application Publication No. 2009/0121908
Patent Document 3: Japanese Patent Application Publication No. 2014-10010

### BRIEF DESCRIPTION OF THE DRAWINGS

FIG. 1 illustrates a configuration of a testing apparatus 1 according to the present embodiment.

FIG. 2 illustrates a configuration of a pin electronics apparatus 200 according to a comparative example of the present embodiment.

FIG. 3 illustrates a configuration of a pin electronics apparatus 300 according to the present embodiment.

FIG. 4 illustrates an operational flow of a functional test of a device under test 10 by the testing apparatus 1 according to the present embodiment.

FIG. 5 illustrates an operational flow of a voltage application current measurement test of the device under test 10 by the testing apparatus 1 according to the present embodiment.

FIG. 6 illustrates an operational flow of a current application voltage measurement test of the device under test 10 by the testing apparatus 1 according to the present embodiment.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solving means of the invention.

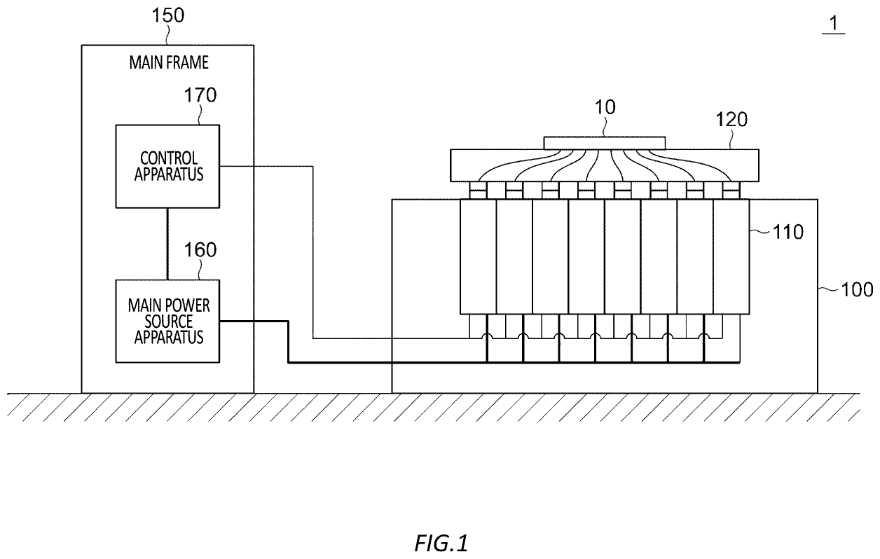

FIG. 1 illustrates a configuration of a testing apparatus 1 according to the present embodiment together with a device under test (DUT) 10. The device under test 10 is a device in which a circuit subjected to a test by the testing apparatus 1 is formed. The device under test 10 may be a wafer in which circuits are formed, an IC/LSI chip obtained by singulation of the wafer, an IC/LSI chip package in which the IC/LSI chip is packaged, or the like. In an example of this drawing, the testing apparatus 1 has the single device under test 10 mounted thereto, but instead of this, the testing apparatus 1 may have a plurality of devices under test 10 mounted thereto to simultaneously perform tests.

The testing apparatus 1 performs an electrical test of the device under test 10. Instead of this, or in addition to this, the testing apparatus 1 may perform an optical input/output test of the device under test 10. In the present embodiment, a case where the testing apparatus 1 performs the electrical test of the device under test 10 will be described as an example. When the testing apparatus 1 performs the optical input/output test of the device under test 10, the testing apparatus 1 and the device under test 10 may be connected through an optical connection in addition to an electrical connection.

The testing apparatus 1 includes a test head 100, a plurality of pin electronics apparatuses 110, a connection apparatus 120, and a main frame 150. The test head 100 is an enclosure in which the plurality of pin electronics apparatuses 110 can be mounted. In an example of this drawing, the test head 100 has a plurality of slots into which the plurality of pin electronics apparatuses 110 are inserted.

Each of the plurality of pin electronics apparatuses 110 is inserted into the slot of the test head 100 and detachably connected to a back plane of the test head 100. The pin electronics apparatus 110 may also be referred to as a “pin electronics card”, a “tester board”, a “test module”, or the like. Each of the pin electronics apparatuses 110 is electrically connected to the device under test 10 via the connection apparatus 120. Each of the pin electronics apparatuses 110 performs input and output of a signal with the device under test 10 and tests the device under test 10 by examining a signal input from the device under test 10.

The connection apparatus 120 is mounted to the test head 100 and electrically connected to the plurality of pin electronics apparatuses 110. The connection apparatus 120 has the device under test 10 mounted thereto and is electrically connected to a plurality of terminals included in the device under test 10. The connection apparatus 120 has a role of serving as an interface for mutual terminals between the plurality of pin electronics apparatuses 110 and the device under test 10 and electrically connects each terminal of one or more devices under test 10 and a corresponding terminal of the plurality of pin electronics apparatuses 110 through a signal cable, a substrate wiring, or the like.

The main frame 150 controls each unit in the testing apparatus 1 to perform a test of the device under test 10. In the present embodiment, the main frame 150 is an enclosure different from the enclosure in which the test head 100 and the like are provided. Instead of this, each configuration in the main frame 150 may be provided in a same enclosure as that for the test head 100. The main frame 150 has a main power source apparatus 160 and a control apparatus 170.

The main power source apparatus 160 receives power supply from a commercial power source or the like and supplies power to each of apparatuses, circuits, and the like in the testing apparatus 1. The control apparatus 170 is connected to the main power source apparatus 160 to receive power supply from the main power source apparatus 160. The control apparatus 170 controls the test of the device under test 10. The control apparatus 170, when achieved by a computer, may control the test of the device under test 10 by executing a test control program.

The control apparatus 170 supplies a test program to each of the pin electronics apparatuses 110 and causes the supplied test program to be executed by each of the pin electronics apparatuses 110 to cause the device under test 10 to be tested. The control apparatus 170 collects and records a test result of the device under test 10 from each of the pin electronics apparatuses 110.

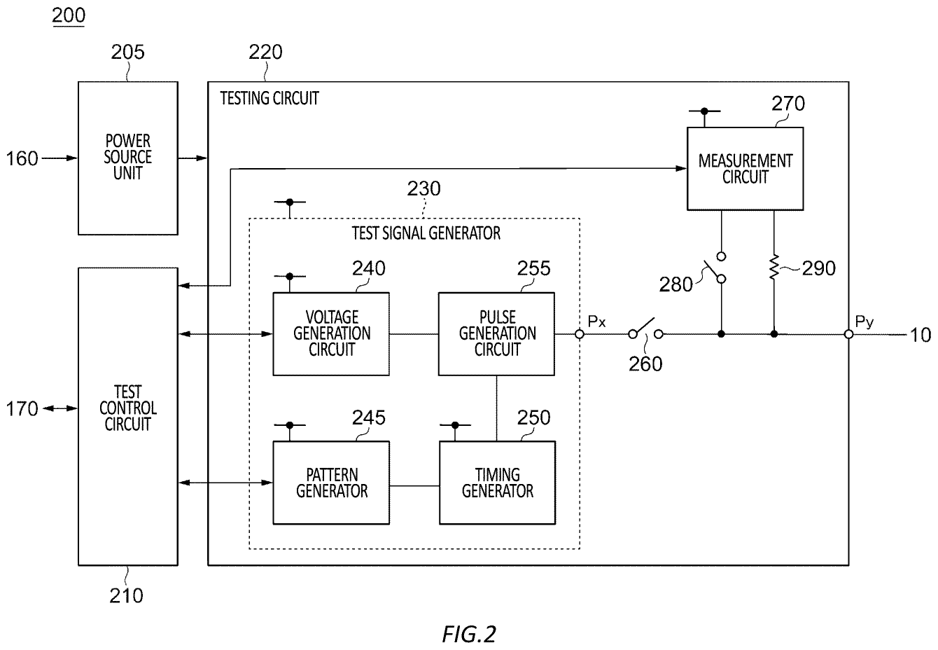

FIG. 2 illustrates a configuration of a pin electronics apparatus 200 according to a comparative example of the present embodiment. The pin electronics apparatus 200 according to the comparative example may be used as the pin electronics apparatus 110 in the testing apparatus 1. The pin electronics apparatus 200 includes a power source unit 205, a testing circuit 220, and a test control circuit 210.

The power source unit 205 receives power supply from the main power source apparatus 160 to generate power to be supplied to each circuit in the pin electronics apparatus 200 and supplies power to each circuit in the pin electronics apparatus 200. The power source unit 205 may have a plurality of power sources and output power of a plurality of types in which rated voltages, rated currents, or the like are different from each other.

The testing circuit 220 is connected to the device under test 10 via the connection apparatus 120, receives power supply from the power source unit 205, and tests the device under test 10. This drawing illustrates a circuit portion corresponding to a single terminal of the device under test 10 in the testing circuit 220 in a representative manner. The testing circuit 220 may be connected to a plurality of terminals and have a circuit portion corresponding to each of the terminals.

In order to perform an operational test (also illustrated as a “functional test”) of the device under test 10, the testing circuit 220 has a test signal generator 230. The test signal generator 230 receives power supply from the power source unit 205 and control by the test control circuit 210 to generate a test signal to be supplied to the device under test 10 in the functional test of the device under test 10 and supplies the test signal to the terminal of the device under test 10. Herein, the test signal generated by the test signal generator 230 may be a pulse signal having a desired signal pattern such as a digital signal or a multi-value signal that is to be supplied to the device under test 10.

The test signal generator 230 has a voltage generation circuit 240, a pattern generator 245, a timing generator 250, and a pulse generation circuit 255. The voltage generation circuit 240 receives power supply from the power source unit 205 and control by the test control circuit 210 to generate, as an output voltage, a power source voltage required by the pulse generation circuit 255 in the functional test. The voltage generation circuit 240 may supply, to the pulse generation circuit 255, a power source voltage according to a voltage at high level in a pulse signal that is to be supplied to the terminal of the device under test 10 as the output voltage.

The pattern generator 245 receives power supply from the power source unit 205 and control by the test control circuit 210 and generates a test pattern which designates a waveform of the pulse signal that is to be supplied to the terminal of the device under test 10 in the functional test. The pattern generator 245 may execute a test command for each test cycle which has a predetermined period and output the test pattern associated with the test command. The test pattern for each test cycle designates a change pattern of the test signal in the test cycle. The pattern generator 245 may be possible to designate, although it varies depending on a model, a pattern identifier representing a waveform shape such as, for example, return to zero (RZ) or non return to zero (NRZ), a polarity of the waveform shape, and the like as the change pattern of such a test signal.

The timing generator 250 receives power supply from the power source unit 205 and control by the test control circuit 210 and generates a change timing of the pulse signal that is to be supplied to the terminal of the device under test 10 in the functional test. The timing generator 250 generates a waveform of the pulse signal that is to be supplied to the device under test 10 by imparting the change timing in real time to the change pattern of the test signal for each test cycle. Note that depending on a model of the testing apparatus 1, the pattern generator 245 may generate a test pattern for each test cycle, the timing generator 250 may generate a timing for each test cycle, and a waveform shaper may shape a waveform of the pulse signal that is to be supplied to the device under test 10 by using the timing by the timing generator 250.

The pulse generation circuit 255 receives the output voltage from the voltage generation circuit 240 and generates a pulse signal by using the output voltage from the voltage generation circuit 240 to be supplied to the terminal of the device under test 10 in the functional test. The pulse generation circuit 255 may drive an output according to the waveform of the test signal to which the change timing in real time has been imparted for each test cycle to high level or low level (in a binary case) or drive the output to each of the multi-value levels to output a pulse signal obtained by changing the test pattern created by the pattern generator 245 at the timing created by the timing generator 250.

The test signal generator 230 illustrated above may be achieved by a set of a discrete IC, an LSI, or an ASIC or may be achieved by a single test signal generation ASIC. The test signal generator 230 may further have a function of receiving a response signal output by the device under test 10 according to the test signal and determining pass or fail or the like of the device under test 10. In this case, the test signal generator 230 may have a comparator which compares the response signal from the device under test 10 with a target value and a determinator which determines pass or fail of the device under test 10 by using a comparison result by the comparator.

A relay 260 is provided between a terminal Py of the testing circuit 220 which is connected to the terminal of the device under test 10 and the test signal generator 230. The relay 260 may be a mechanical relay or may be a semiconductor relay using a semiconductor switch or the like. The relay 260 is turned on by the test control circuit 210 or the like when the functional test of the device under test 10 is performed, and connects the test signal generator 230 and the terminal of the device under test 10. On the other hand, the relay 260 is turned off by the test control circuit 210 or the like when a parametric test (a voltage application current measurement test, a current application voltage measurement test, or the like) of the device under test 10 by a measurement circuit 270 is performed, and disconnects the test signal generator 230 and the terminal of the device under test 10.

The measurement circuit 270 is connected to a wiring between a terminal from which the test signal generator 230 outputs the pulse signal and the terminal of the device under test 10. In an example of this drawing, the measurement circuit 270 is connected to a force line through which a voltage or a current is applied to the terminal of the device under test 10 via a relay 280 and a sense line for sensing a voltage of the terminal of the device under test 10 via a resistance 290. The force line and the sense line are connected to a wiring between the relay 260 and the terminal Py of the testing circuit 220 connected to the terminal of the device under test 10.

The measurement circuit 270 receives power supply from the power source unit 205 and control by the test control circuit 210 and performs the parametric test of the device under test 10. Depending on a model, as an example, the measurement circuit 270 may include various circuits including at least one of a voltage generator which generates a voltage to be supplied to the terminal of the device under test 10, a current generator which generates a current to be supplied to the device under test 10, a voltage measuring instrument which measures a voltage output by the device under test 10, a current measuring instrument which measures a current output by the device under test 10, a frequency measuring instrument which measures a frequency of a signal output by the device under test 10, or the like. In an example of this drawing, the measurement circuit 270 is provided in the pin electronics apparatus 200. Instead of this, the measurement circuit 270 may be achieved by another pin electronics apparatus 110 in the testing apparatus 1.

When the voltage application current measurement test is performed, the measurement circuit 270 outputs a desired test voltage via the force line and measures a current which flows through the terminal of the device under test 10 which has received the test voltage. When the current application voltage measurement test is performed, the measurement circuit 270 causes a desired test current to flow between the measurement circuit 270 and the terminal of the device under test 10 via the force line and measures the voltage of the terminal of the device under test 10 via the sense line.

The relay 280 is provided in a force line between the measurement circuit 270 and a connection point on a terminal Py side relative to the relay 260 in a wiring between the terminal Py of the testing circuit 220 and the test signal generator 230. The relay 280 may be a mechanical relay or may be a semiconductor relay using a semiconductor switch or the like. The relay 280 is turned off by the test control circuit 210 or the like when the functional test of the device under test 10 is performed, and disconnects the measurement circuit 270 and the terminal of the device under test 10. The relay 280 is turned on by the test control circuit 210 or the like when the parametric test of the device under test 10 is performed, and connects the measurement circuit 270 and the terminal of the device under test 10.

The resistance 290 is provided in a sense line between the measurement circuit 270 and the connection point on the terminal Py side relative to the relay 260 in the wiring between the terminal Py of the testing circuit 220 and the test signal generator 230. The resistance 290 may be a relatively large resistance such as, for example 10 KΩ, and allows the voltage of the terminal of the device under test 10 to be input to the measurement circuit 270 while the terminal of the device under test 10 and the measurement circuit 270 are substantially isolated.

The test control circuit 210 controls a test of the device under test 10 by the testing circuit 220. The test control circuit 210 may be also referred to as a “site controller”. By executing a test program supplied from the control apparatus 170 and controlling each unit in the testing circuit 220, the test control circuit 210 causes the testing circuit 220 to perform a test such as the operational test or the parametric test of the device under test 10.

In the pin electronics apparatus 200 described above, the measurement circuit 270 is connected to a wiring between a terminal Px from which the test signal generator 230 outputs a pulse signal and the terminal of the device under test 10. In the functional test of the device under test 10, a high speed pulse signal is transmitted through the wiring between the terminal Px of the test signal generator 230 and the terminal of the device under test 10. Herein, the relay 260 is set to be on, and the relay 280 is set to be off in the functional test of the device under test 10, but the relay 260 has a parasitic capacitance even when it is on, and the relay 280 has a parasitic capacitance even when it is off. Thus, the wiring between the terminal Px of the test signal generator 230 and the terminal of the device under test 10 causes RC delay by the parasitic capacitances of the relay 260 and the relay 280, and transmission of the high speed pulse signal is disrupted.

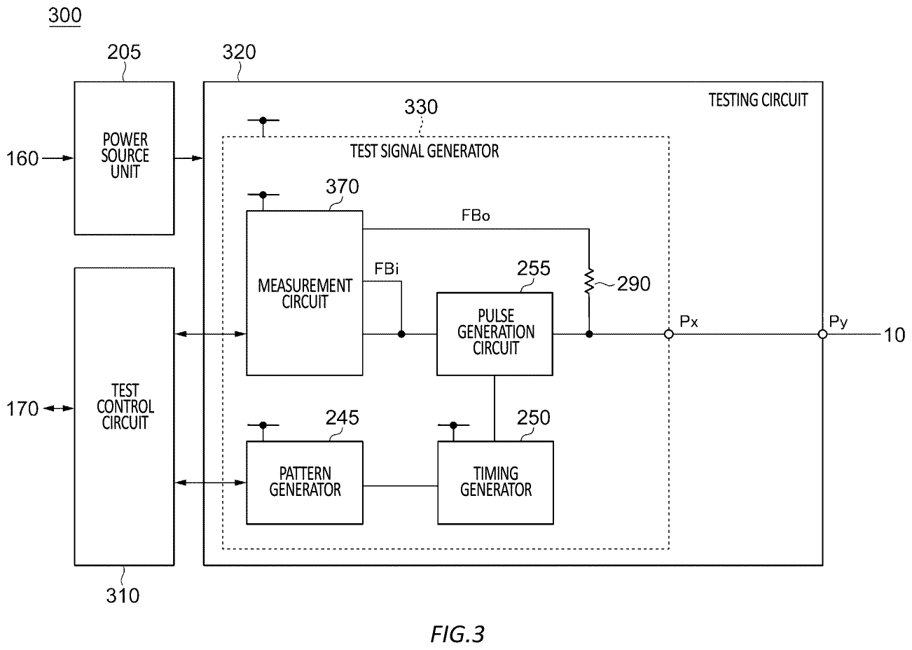

FIG. 3 illustrates a configuration of a pin electronics apparatus 300 according to the present embodiment. The pin electronics apparatus 300 is a modified example of the pin electronics apparatus 200. In this drawing, components with same reference numerals as those in FIG. 2 have similar functions and configurations to those in FIG. 2 and therefore will not be described below except for differences.

A testing circuit 320 is connected to the device under test 10 via the connection apparatus 120, receives power supply from the power source unit 205, and tests the device under test 10. This drawing illustrates a circuit portion corresponding to a single terminal of the device under test 10 in the testing circuit 320 in a representative manner. The testing circuit 320 may be connected to a plurality of terminals and have a circuit portion corresponding to each of the terminals.

The testing circuit 320 has a test signal generator 330. The test signal generator 330 according to the present embodiment receives power supply from the power source unit 205 and control by a test control circuit 310 and performs both the functional test and the parametric test of the device under test 10. The testing circuit 320 may perform both the functional test and the parametric test on the same device under test 10 according to a use method by a user. The testing circuit 320 may perform the functional test on a certain device under test 10 and perform the parametric test on a different device under test 10. In addition, depending on the use method of the user, the testing circuit 320 may perform only one of the functional test or the parametric test, and a function of performing the other test does not necessarily need to be used. The test signal generator 330 has a measurement circuit 370, the pattern generator 245, the timing generator 250, the pulse generation circuit 255, and the resistance 290.

The measurement circuit 370 receives power supply from the power source unit 205 and control by the test control circuit 310. The measurement circuit 370 performs the parametric test of the device under test 10. Although it may vary depending on a type of the parametric test to be supported, as an example, the measurement circuit 370 may include various circuits including at least one of a voltage generator which generates a voltage to be supplied to the terminal of the device under test 10, a current generator which generates a current to be supplied to the device under test 10, a voltage measuring instrument which measures a voltage output by the device under test 10, a current measuring instrument which measures a current output by the device under test 10, a frequency measuring instrument which measures a frequency of a signal output by the device under test 10, or the like.

The measurement circuit 370 according to the present embodiment may be possible to perform, as the parametric test, at least one of the voltage application current measurement test or the current application voltage measurement test. In the voltage application current measurement test, the measurement circuit 370 generates an output voltage and performs the voltage application current measurement test of the device under test 10 by using the output voltage. The output voltage of the measurement circuit 370 is supplied to the terminal of the device under test 10 as a test voltage via the pulse generation circuit 255. In the current application voltage measurement test, the measurement circuit 370 generates an output current and performs the current application voltage measurement test of the device under test 10 by using this output current. The output current of the measurement circuit 370 is supplied to the terminal of the device under test 10 as a test current via the pulse generation circuit 255. Herein, the output current of the measurement circuit 370 may be a positive current, that is, a current (source current) which flows towards the terminal of the device under test 10 from the measurement circuit 370 or may be a negative current, that is, a current (sink current) which flows towards the measurement circuit 370 from the terminal of the device under test 10.

In the functional test, similarly as in the voltage generation circuit 240 illustrated in FIG. 2, the measurement circuit 370 generates, as the output voltage, a power source voltage required by the pulse generation circuit 255 in the functional test. The voltage generation circuit 240 may supply, to the pulse generation circuit 255, a power source voltage according to a voltage at high level in a pulse signal that is to be supplied to the terminal of the device under test 10 as the output voltage.

The pattern generator 245, the timing generator 250, and the pulse generation circuit 255 have similar functions and configurations to those in the pattern generator 245, the timing generator 250, and the pulse generation circuit 255 illustrated in FIG. 2. The pulse generation circuit 255 generates a pulse signal by using the output voltage of the measurement circuit 370 in the functional test of the device under test 10 and supplies the generated pulse signal to the terminal of the device under test 10. The pulse generation circuit 255 causes the output voltage of the measurement circuit 370 to pass therethrough in the voltage application current measurement test and supplies this output voltage that has passed to the terminal of the device under test 10 as a test voltage. The pulse generation circuit 255 causes the output current of the measurement circuit 370 to pass therethrough in the current application voltage measurement test and supplies this output current that has passed as a test current to the terminal of the device under test 10. Note that the testing circuit 320 may generate a pulse signal by the pulse generation circuit 255 by using any circuit other than the pattern generator 245 and the timing generator 250.

Since the pulse generation circuit 255 has a function of outputting a digital signal or a multi-value signal in the functional test, at least one signal value (for example, high level in the digital signal or a maximum value in the multi-value signal), the pulse generation circuit 255 causes the output voltage supplied from the measurement circuit 370 to pass therethrough via at least one of a resistance or a switching device in the pulse generation circuit 255 and outputs this output voltage that has passed to the terminal of the device under test 10. By performing control such that the pulse generation circuit 255 regularly outputs such a signal value during the parametric test, the control apparatus 170, the test control circuit 210, or the pattern generator 245 and the timing generator 250, or the like can connect an input end and an output end of the pulse generation circuit 255 via at least one of the resistance or the switching device and supply the output voltage or the output current of the measurement circuit 370 as the test voltage or the test current to the device under test 10 via the pulse generation circuit 255.

The test signal generator 330 may include an output end feedback line FBo which is connected to an output end side of the pulse generation circuit 255 and causes a voltage on the output end side to be fed back to the measurement circuit 370. The output end feedback line FBo may have a function similar to that of the sense line of the voltage which is illustrated in FIG. 2 and is connected to a connection point on a wiring between the output end of the pulse generation circuit 255 and the terminal of the device under test 10 and feeds back a voltage of this connection point to the measurement circuit 370. This connection point in the pin electronics apparatus 300 according to the present embodiment is provided in a vicinity of the output end of the pulse generation circuit 255 in the test signal generator 330. Instead of this, this connection point may be provided outside the test signal generator 330 in the testing circuit 320 and may be provided outside the testing circuit 320, for example, in a vicinity of the terminal of the device under test 10 or the like. The resistance 290 may be provided in the output end feedback line FBo. The resistance 290 has a function and a configuration similar to those of the resistance 290 illustrated in FIG. 2.

The test signal generator 330 may include an input end feedback line FBi which is connected to an input end side of the pulse generation circuit 255 and causes a voltage of the input end side to be fed back to the measurement circuit 370. In an embodiment including the input end feedback line FBi, the measurement circuit 370 may adjust the output voltage by using the voltage fed back from the input end feedback line in the functional test. Note that a resistance may be provided in the input end feedback line FBi similarly as in the resistance 290 in the output end feedback line FBo.

In accordance with the pin electronics apparatus 300 described above, the functions of both the measurement circuit 270 and the voltage generation circuit 240 illustrated in FIG. 2 are achieved by the measurement circuit 370. According to this, the voltage generation circuit 240 which generates the output voltage for the pulse generation circuit 255 in the functional test in the configuration illustrated in FIG. 2 and the voltage generation circuit in the measurement circuit 270 which generates the test voltage in the voltage application current measurement test can be replaced with the voltage generation circuit in the measurement circuit 370 to be shared in the functional test and the voltage application current measurement test, so that a circuit scale of the pin electronics apparatus 300 can be reduced.

In addition, in accordance with the pin electronics apparatus 300 described above, it does not need to connect the force line of the measurement circuit 270 to the wiring from the pulse generation circuit 255 to the terminal of the device under test 10, so that the relay 260 and the relay 280 are not required. According to this, the circuit scale of the pin electronics apparatus 300 can be reduced, and a deterioration of the high speed pulse signal can be avoided by removing the parasitic capacitances of the relay 260 and the relay 280. Note that in the pin electronics apparatus 300 according to the present embodiment too, the output end feedback line FBo (equivalent to the sense line in FIG. 2) is connected to the wiring from the pulse generation circuit 255 to the terminal of the device under test 10. Herein, the output end feedback line FBo has the resistance 290 with a relatively large resistance value and feeds back the voltage of the terminal of the device under test 10 to the measurement circuit 370 while the wiring from the pulse generation circuit 255 to the terminal of the device under test 10 and the measurement circuit 370 are substantially isolated. Accordingly, the deterioration of the high speed pulse signal caused by the output end feedback line FBo is minute.

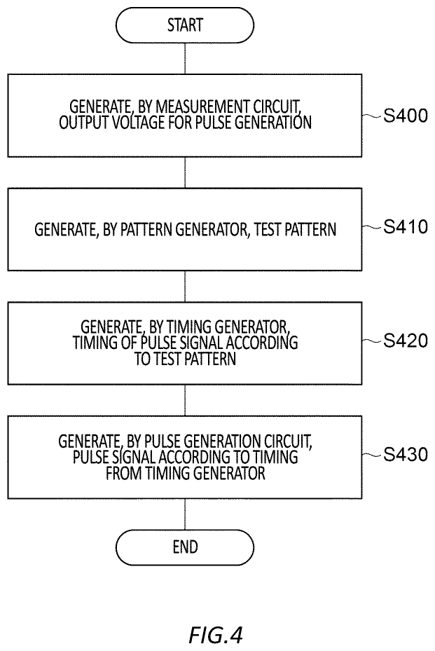

FIG. 4 illustrates an operational flow of the functional test of the device under test 10 by the testing apparatus 1 according to the present embodiment while focusing on an operation of the pin electronics apparatus 300 of FIG. 3. Before the present operational flow is started, the testing apparatus 1 electrically connects one or more pin electronics apparatuses 300 to the device under test 10 via the connection apparatus 120.

In step S400, the measurement circuit 370 receives control of the test control circuit 310 and generates, as an output voltage, a power source voltage for pulse generation required by the pulse generation circuit 255 in the functional test. In the functional test, the measurement circuit 370 may adjust the output voltage by using a voltage fed back from the input end feedback line FBi.

For example, the measurement circuit 370 compares the feedback voltage fed back from the input end feedback line FBi with a target output voltage. The measurement circuit 370 causes the output voltage to increase when the feedback voltage is lower than the target output voltage, and causes the output voltage to fall when the feedback voltage is higher than the target output voltage. According to this, the measurement circuit 370 can adjust the output voltage to be close to the target output voltage. Note that the measurement circuit 370 may perform the feedback and adjustment of the output voltage inside the measurement circuit 370.

In S410, the pattern generator 245 receives control of the test control circuit 310 and generates a test pattern for each test cycle. In S420, the timing generator 250 receives control of the test control circuit 310 and generates a timing of a pulse signal according to the test pattern for each test cycle. In S430, the pulse generation circuit 255 generates a pulse signal according to the timing from the timing generator 250 for each test cycle by using the output voltage of the measurement circuit 370 and supplies this generated pulse signal to the terminal of the device under test 10. The pin electronics apparatus 300 may receive a response signal output by the device under test 10 according to the test signal and determines pass or fail or the like of the device under test 10.

In accordance with the pin electronics apparatus 300 described above, by using the voltage generator in the measurement circuit 370 used for the parametric test of the device under test 10, the power source voltage required by the pulse generation circuit 255 in the functional test can be supplied. In addition, the measurement circuit 370 can adjust the output voltage by using the feedback voltage from the input end feedback line FBi to reduce an error from the target output voltage.

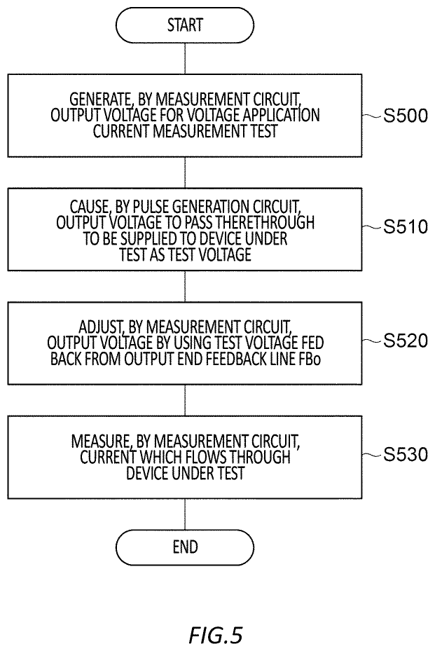

FIG. 5 illustrates an operational flow of the voltage application current measurement test of the device under test 10 by the testing apparatus 1 according to the present embodiment while focusing on an operation of the pin electronics apparatus 300 of FIG. 3. Before the present operational flow is started, the testing apparatus 1 electrically connects one or more pin electronics apparatuses 300 to the device under test 10 via the connection apparatus 120.

In S500, the measurement circuit 370 generates an output voltage for the voltage application current measurement test. In S510, the pulse generation circuit 255 causes the output voltage of the measurement circuit 370 which is input from the measurement circuit 370 to pass therethrough and supplies this output voltage that has passed to the terminal of the device under test 10 as a test voltage.

In S520, the measurement circuit 370 adjusts the output voltage by using a test voltage fed back from the output end feedback line. For example, the measurement circuit 370 compares the test voltage fed back from the output end feedback line FBo with a target test voltage. The measurement circuit 370 causes the output voltage to increase when the test voltage that is fed back is lower than the target test voltage, and causes the output voltage to fall when the test voltage that is fed back is higher than the target test voltage. According to this, in a configuration in which the test voltage is supplied to the terminal of the device under test 10 via the pulse generation circuit 255, even when a resistance exists between the input end and the output end of the pulse generation circuit 255, the measurement circuit 370 can adjust the test voltage on the output end side of the pulse generation circuit 255 to be close to the target value.

In S530, the measurement circuit 370 measures a current which flows through the terminal of the device under test 10 in a state in which the test voltage is supplied to the terminal of the device under test 10. The measurement circuit 370 according to the present embodiment measures the current which flows through the terminal of the device under test 10 by using the resistance connected between the input end and the output end of the pulse generation circuit 255 as a sense resistance. In this case, the measurement circuit 370 measures the current which flows through the terminal of the device under test 10 by using a potential difference between the input end feedback line FBi and the output end feedback line FBo. For example, an internal resistance of the pulse generation circuit 255 when the output voltage of the measurement circuit 370 is caused to pass from an input end to an output end is denoted as R, a voltage of the input end of the pulse generation circuit 255 which is measured by using the input end feedback line FBi is denoted as Vi, and a voltage of the output end of the pulse generation circuit 255 which is measured by using the output end feedback line FBo is denoted as Vo. The current which flows through the terminal of the device under test 10 is substantially the same as the current which flows through the pulse generation circuit 255 and takes a value obtained by dividing a potential difference (Vi−Vo) between the input end feedback line FBi and the output end feedback line FBo by the internal resistance R.

In accordance with the pin electronics apparatus 300 described above, the voltage application current measurement test of the device under test 10 can be performed via the pulse generation circuit 255 used for the functional test of the device under test 10. The measurement circuit 370 can measure the test voltage on the output end side of the pulse generation circuit 255 and adjust the output voltage. In addition, the measurement circuit 370 can calculate the current which flows through the terminal of the device under test 10 by using the internal resistance of the pulse generation circuit 255.

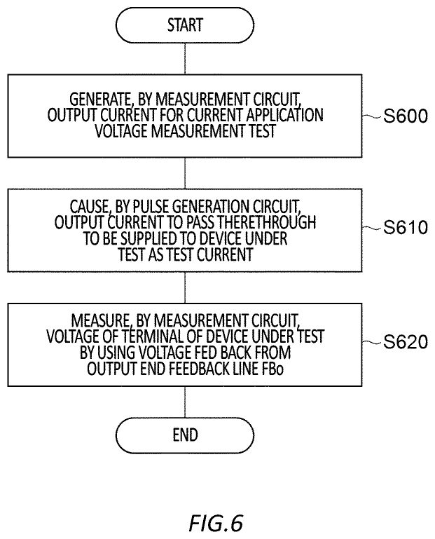

FIG. 6 illustrates an operational flow of the current application voltage measurement test of the device under test 10 by the testing apparatus 1 according to the present embodiment while focusing on an operation of the pin electronics apparatus 300. Before the present operational flow is started, the testing apparatus 1 electrically connects one or more pin electronics apparatuses 300 to the device under test 10 via the connection apparatus 120.

In S600, the measurement circuit 370 generates an output current for the current application voltage measurement test. This output current may be either a positive current or a negative current according to a test content. In S610, the pulse generation circuit 255 causes the output current of the measurement circuit 370 which is input from the measurement circuit 370 to pass therethrough and supplies this output current that has passed to the terminal of the device under test 10 as a test current.

In S620, the measurement circuit 370 measures a voltage fed back from the output end feedback line FBo. The measurement circuit 370 may measure or calculate the voltage of the terminal of the device under test 10 by using the measured voltage. For example, when a wiring resistance from a connection point of the output end feedback line FBo to the terminal of the device under test 10 in a wiring from the output end of the pulse generation circuit 255 to the terminal of the device under test 10 is negligible, the measurement circuit 370 may measure a voltage fed back from the output end feedback line FBo as the voltage of the terminal of the device under test 10. When the wiring resistance from the connection point of the output end feedback line FBo to the terminal of the device under test 10 in the wiring from the output end of the pulse generation circuit 255 to the terminal of the device under test 10 is taken into account, the measurement circuit 370 may calculate the voltage of the terminal of the device under test 10 by adding, to the measured voltage, a voltage drop (in a case of a positive current) or a voltage increase (in a case of a negative current) which is caused when the test current flows through the known wiring resistance.

In accordance with the pin electronics apparatus 300 illustrated above, the current application voltage measurement test of the device under test 10 can be performed via the pulse generation circuit 255 used for the functional test of the device under test 10. The measurement circuit 370 can measure the voltage of the terminal of the device under test 10 on the output end side of the pulse generation circuit 255.

Note that in S600 and S610, as illustrated in relation to S530 of FIG. 5, the measurement circuit 370 may measure a current which flows through the terminal of the device under test 10 by using the potential difference between the input end feedback line FBi and the output end feedback line FBo and adjust the test current by using the measured current. For example, the measurement circuit 370 compares the measured current with a target test current. The measurement circuit 370 causes the output current to increase when the measured current is smaller than the target test current, and causes the output current to fall when the measured current is greater than the target test current. According to this, in a configuration in which the test current is supplied to the terminal of the device under test 10 via the pulse generation circuit 255, the measurement circuit 370 can adjust the test current to be close to the target value.

While the embodiments of the present invention have been described, the technical scope of the present invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the present invention.

The operations, procedures, steps, stages, and the like of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

1: testing apparatus; 10: device under test; 100: test head; 110: pin electronics apparatus; 120: connection apparatus; 150: main frame; 160: main power source apparatus; 170: control apparatus; 200: pin electronics apparatus; 205: power source unit; 210: test control circuit; 220: testing circuit; 230: test signal generator; 240: voltage generation circuit; 245: pattern generator; 250: timing generator; 255: pulse generation circuit; 260: relay; 270: measurement circuit; 280: relay; 290: resistance; 300: pin electronics apparatus; 310: test control circuit; 320: testing circuit; 330: test signal generator; 370: measurement circuit; FBi: input end feedback line; and FBo: output end feedback line.

What is claimed is:

1. A testing circuit comprising:
a measurement circuit which generates an output voltage and performs a voltage application current measurement test of a device under test by using the output voltage;
a pulse generation circuit which generates a pulse signal by using the output voltage of the measurement circuit in a functional test of a device under test to supply the pulse signal to a terminal of a device under test and causes the output voltage of the measurement circuit to pass therethrough in the voltage application current measurement test to supply the output voltage to a terminal of a device under test as a test voltage; and
an output end feedback line which is connected to an output end side of the pulse generation circuit and feeds back a voltage on the output end side to the measurement circuit.

2. The testing circuit according to claim 1, wherein
the pulse generation circuit
generates a pulse signal having a plurality of signal values by using the output voltage of the measurement circuit in the functional test to supply the pulse signal to a terminal of a device under test, and
causes the output voltage of the measurement circuit to pass therethrough by regularly outputting a signal value at which the output voltage is caused to pass therethrough among the plurality of signal values in the voltage application current measurement test to supply the output voltage to a terminal of a device under test as the test voltage.

3. The testing circuit according to claim 1, wherein in the voltage application current measurement test, the measurement circuit adjusts the output voltage by using the test voltage fed back from the output end feedback line.

4. The testing circuit according to claim 1, further comprising an input end feedback line which is connected to an input end side of the pulse generation circuit and feeds back a voltage of the input end side to the measurement circuit.

5. The testing circuit according to claim 4, wherein in the functional test, the measurement circuit adjusts the output voltage by using a voltage fed back from the input end feedback line.

6. The testing circuit according to claim 4, wherein
the pulse generation circuit has a resistance connected between the input end and the output end, and
in the voltage application current measurement test, the measurement circuit measures a current which flows through a terminal of a device under test by using a potential difference between the input end feedback line and the output end feedback line.

7. The testing circuit according to claim 1, wherein
the measurement circuit generates an output current and performs a current application voltage measurement test of a device under test by using the output current, and
the pulse generation circuit causes the output current of the measurement circuit to pass therethrough in the current application voltage measurement test to supply the output current to a terminal of a device under test as a test current.

8. The testing circuit according to claim 7, wherein in the current application voltage measurement test, the measurement circuit measures a voltage fed back from the output end feedback line.

9. A testing apparatus comprising the testing circuit according to claim 1.

10. A testing method comprising:
generating, by a measurement circuit, an output voltage and performing a voltage application current measurement test of a device under test by using the output voltage;
generating, by a pulse generation circuit, a pulse signal by using the output voltage of the measurement circuit in a functional test of a device under test to supply the pulse signal to a terminal of a device under test and causing the output voltage of the measurement circuit to pass therethrough in the voltage application current measurement test to supply the output voltage to a terminal of a device under test as a test voltage; and
feeding back, by an output end feedback line connected to an output end side of the pulse generation circuit, a voltage on the output end side to the measurement circuit.

11. The testing method according to claim 10, wherein
the pulse generation circuit
generates a pulse signal having a plurality of signal values by using the output voltage of the measurement circuit in the functional test to supply the pulse signal to a terminal of a device under test, and
causes the output voltage of the measurement circuit to pass therethrough by regularly outputting a signal value at which the output voltage is caused to pass therethrough among the plurality of signal values in the voltage application current measurement test to supply the output voltage to a terminal of a device under test as a test voltage.

12. The testing method according to claim 10, wherein in the voltage application current measurement test, the measurement circuit adjusts the output voltage by using the test voltage fed back from the output end feedback line.

13. The testing method according to claim 10, further comprising feeding back, by an input end feedback line connected to an input end side of the pulse generation circuit, a voltage of the input end side to the measurement circuit.

14. The testing method according to claim 13, wherein in the functional test, the measurement circuit adjusts the output voltage by using a voltage fed back from the input end feedback line.

15. The testing method according to claim 13, wherein
the pulse generation circuit has a resistance connected between the input end and the output end, and
in the voltage application current measurement test, the measurement circuit measures a current which flows through a terminal of a device under test by using a potential difference between the input end feedback line and the output end feedback line.

16. The testing method according to claim 10, wherein
the measurement circuit generates an output current and performs a current application voltage measurement test of a device under test by using the output current, and
the pulse generation circuit causes the output current of the measurement circuit to pass therethrough in the current application voltage measurement test to supply the output current to a terminal of a device under test as a test current.

17. The testing method according to claim 16, wherein in the current application voltage measurement test, the measurement circuit measures a voltage fed back from the output end feedback line.
